(19) United States
(12) Patent Application Publication
(10) Pub. No.: US 2021/0392773 A1
(43) Pub. Date: Dec. 16, 2021

(54) CASES FOR MOBILE DEVICES HAVING A WINDOW TO FACILITATE HEAT DISSIPATION AND METHODS OF MAKING AND USING

(71) Applicant: National Products, Inc., Seattle, WA (US)

(72) Inventor: Jeffrey D. Carnevali, Seattle, WA (US)

(21) Appl. No.: 16/928,952

(22) Filed: Jul. 14, 2020

Related U.S. Application Data
(63) Continuation-in-part of application No. 16/898,299, filed on Jun. 10, 2020.

(51) Int. Cl. H05K 7/14; H05K 7/20; H01R 13/516

(52) U.S. Cl. CPC H05K 7/1438; H01R 13/516; H05K 7/20172

(57) ABSTRACT

A case for a mobile device includes a cover defining a cavity configured for receiving and holding the mobile device, the cover including a back panel and a window formed in the back panel; a male plug disposed in the second portion of the cover, extending into the cavity defined by the cover, and configured for insertion into a female socket of the mobile device, the male plug including first contacts configured for mating with contacts of the mobile device; and an accessory attachment coupleable to the cover and including a fan configured to be positioned over the window formed in the back panel of the cover to facilitate heat dissipation from the mobile device.

### CROSS-REFERENCE TO RELATED APPLICATIONS

This patent application is a continuation-in-part of U.S. patent application Ser. No. 16/898,299, filed Jun. 10, 2020, which is incorporated herein by reference.

### FIELD

The present invention is directed to cases for a mobile device. The present invention is also directed to cases for a mobile device that includes a window to facilitate heat dissipation.

### BACKGROUND

Mobile devices, such as smartphones, cellular or mobile phones, tablets, personal data assistants, and other portable devices, are now ubiquitous. Cases are typically used to protect the mobile device.

### BRIEF SUMMARY

One embodiment is a case for a mobile device. The case includes a cover defining a cavity configured for receiving and holding the mobile device, the cover including a back panel and a window formed in the back panel, wherein the window includes at least 30% of the area of the back panel; a male plug disposed in the second portion of the cover, extending into the cavity defined by the cover, and configured for insertion into a female socket of the mobile device, the male plug including a plurality of first contacts configured for mating with contacts of the mobile device; and an accessory attachment coupleable to the cover and including a fan configured to be positioned over the window formed in the back panel of the cover to facilitate heat dissipation from the mobile device.

Another embodiment is a case for a mobile device. The case includes a cover defining a cavity sized for receiving and holding the mobile device, the cover including a back panel and a window formed in the back panel, wherein the window includes at least 30% of the area of a back surface of the mobile device; a male plug disposed in the second portion of the cover, extending into the cavity defined by the cover, and configured for insertion into a female socket of the mobile device, the male plug including a plurality of first contacts configured for mating with contacts of the mobile device; and an accessory attachment coupleable to the cover and including a fan configured to be positioned over the window formed in the back panel of the cover to facilitate heat dissipation from the mobile device.

In at least some embodiments, the accessory attachment further includes a fitting on the fan for attachment to a source of cooling air. In at least some embodiments, the cover further includes a raised rim around at least a portion of the window and extending away from an adjacent portion of the cover. In at least some embodiments, the raised rim extends around an entire perimeter of the window.

In at least some embodiments, the accessory attachment includes a base and at least one attachment arm extending from the base and configured to engage a front surface and a back surface of the cover to attach the accessory attachment to the cover. In at least some embodiments, at least one of the at least one attachment arm includes a roller configured to engage the cover and to roll as the roller is passed over the cover.

In at least some embodiments, the accessory attachment further includes a mounting site configured for attachment of a mount. In at least some embodiments, the accessory attachment further includes a mount. In at least some embodiments, the accessory attachment includes a base with the fan attached to the base and the base defining at least one opening that, when the accessory attachment is coupled to the cover, overlaps with the window of the cover. In at least some embodiments, the accessory attachment includes a base and an attachment tray extending from the base and configured to receive a portion of the cover.

In at least some embodiments, the case further includes a cord extending out of the cover and including a jacket and a plurality of wires disposed in the jacket and electrically coupled to the first contacts of the male plug. In at least some embodiments, the case further includes a contactor disposed in the cover and including a plurality of second contacts electrically coupled to the first contacts of the male plug and exposed for coupling to an external device.

In at least some embodiments, the cover includes a first portion and a second portion removably attachable to the first portion. In at least some embodiments, the cover is a single unitary piece.

Yet another embodiment is an arrangement that includes any of the cases described above and the mobile device receivable within the case and including the female socket configured to receive the male plug of the adapter of the case.

### BRIEF DESCRIPTION OF THE DRAWINGS

Non-limiting and non-exhaustive embodiments of the present invention are described with reference to the following drawings. In the drawings, like reference numerals refer to like parts throughout the various figures unless otherwise specified.

For a better understanding of the present invention, reference will be made to the following Detailed Description, which is to be read in association with the accompanying drawings, wherein:

FIG. 1A is a schematic perspective front view of a first embodiment of a case for a mobile device, according to the invention;

FIG. 1B is a schematic perspective back view of the case of FIG. 1A, according to the invention;

FIG. 1C is a schematic perspective front view of the case of FIG. 1A from a different angle and without the mobile device, according to the invention;

FIG. 2A is a schematic perspective front view of a second portion of a cover of the case of FIG. 1A, according to the invention;

FIG. 2B is a schematic perspective partial cut-away side view of the case of FIG. 1A, according to the invention;

FIG. 2C is a schematic perspective partial cut-away top view of the case of FIG. 1A, according to the invention;

FIG. 3 is a block diagram of a first embodiment of electrical connection between a mobile device, the case of FIG. 1A including the cord of the case, and either a connector on the cord or a device to which the cord is hardwired, according to the invention;

FIG. 4A is a schematic perspective back view of one embodiment of an accessory attachment attached to the case of FIG. 1A, according to the invention;

FIG. 4B is a schematic perspective front view of the accessory attachment and the case of FIG. 4A, according to the invention;

FIG. 5A is a schematic perspective view of one embodiment of a clamp, according to the invention;

FIG. 5B is a schematic perspective view of the clamp of FIG. 5B with two cords and two connectors attached to each other and tied down in the clamp, according to the invention;

FIG. 6 is a schematic perspective back view of an embodiment of a case with a window, according to the invention;

FIG. 7A is a schematic perspective front view of the case of FIG. 6 with one embodiment of an accessory attachment, according to the invention;

FIG. 7B is a schematic perspective front view of the case of FIG. 6 and the accessory attachment of FIG. 7A and a mobile device disposed in the case, according to the invention; and

FIG. 7C is a schematic perspective back view of the case of FIG. 6 with another embodiment of an accessory attachment, according to the invention.

### DETAILED DESCRIPTION

The present invention is directed to cases for a mobile device. The present invention is also directed to cases for a mobile device that includes a cord extending from the case. The present invention is also directed to cases for a mobile device that includes a window to facilitate heat dissipation.

Mobile devices are used in a variety of contexts for interactions with multiple users. For example, a mobile device can be used in a delivery vehicle for managing the deliveries. The driver of the delivery vehicle may pass the mobile device to another person outside the vehicle, for example, for review of the cargo. In addition, the driver may leave the mobile device in the vehicle during meals, deliveries, or at the end of the day or shift. It is beneficial if the mobile device is tethered to the vehicle to prevent or hinder others from permanently removing the mobile device from the vehicle. Similarly, mobile devices can be used as point-of-sale devices to complete transactions with a customer. It is beneficial if the mobile device is tethered to, for example, a counter, cash register, or other article or device to prevent or hinder others from permanently removing the mobile device.

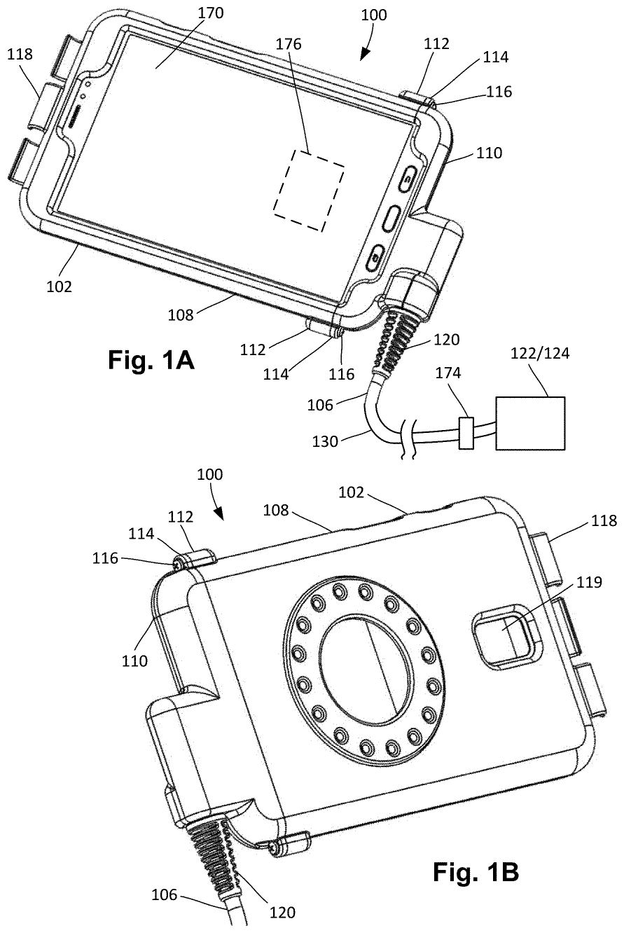

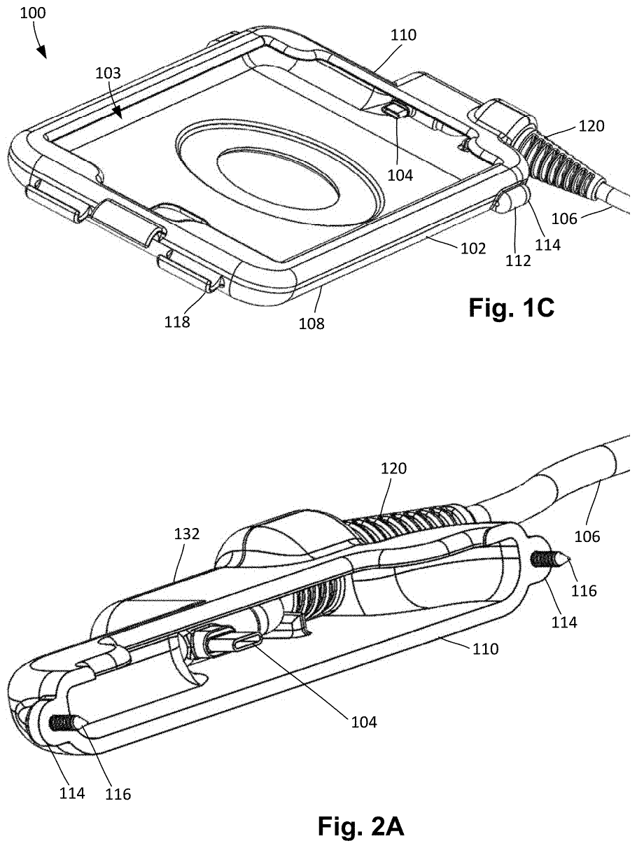

FIGS. 1A to 1C illustrate one embodiment of a case 100 for a mobile device, such as a cellular or mobile phone, a smartphone, a tablet, a personal data assistant, or any other suitable mobile device. The case 100 includes a cover 102 which defines a cavity 103 (FIG. 1C) to receive the mobile device, a male plug 104 (FIG. 1C) which extends from the cover into the cavity, and a cord 106 which extends from the cover, may act as a tether, and may be coupled to a power or data source.

The cover 102 includes a first portion 108 and a second portion 110 removably attachable to the first portion. In at least some embodiments, the first portion 108 includes at least one fastener receiver 112 and the second portion 110 includes at least one fastener ring 114 that aligns with the fastener receiver for insertion of a fastener 116, such as a screw or bolt, to hold the first portion and second portion together. (In other embodiments, the first portion 108 can include at least one fastener ring 114 and the second portion can include at least one fastener receiver 112.) In the illustrated embodiment, the first portion 108 includes two fastener receivers 112 on opposite sides of the cover 102, the second portion 110 includes two fastener rings 114 on opposite sides of the cover, and two fasteners 116 hold the first and second portions together. In at least some embodiments, the mobile device 170 is loaded into the case 100 by separating the first and second portions 108, 110, inserting the mobile device into the cavity 103, and the fastening the second portion to the first portion using the fastener(s) 116. Other arrangements for fastening the first portion 108 to the second portion 110 can be used include snap-fasteners, clip fasteners, or the like or any combination thereof.

The cover 102 can be made of any suitable material including any suitable polymeric material. The cover 102 can be made of a flexible material (for example, thermoplastic elastomeric polymer materials, other suitable flexible or elastomeric polymer materials, or the like or any combination thereof) or a rigid material or any combination thereof. For example, flexible covers that can be modified to include first and second portions 108, 110 and a cord 106 are described in U.S. Pat. Nos. 9,195,279; 9,331,444; 9,529,387; 9,602,639; 9,632,535; 9,706,026; 10,050,658; 10,054,984; 10,389,399; 10,454,515; and 10,630,334 and U.S. patent application Ser. Nos. 16/835,544; 16/853,565; and Ser. No. 16/866,156, all of which are incorporated herein by reference in their entireties.

In some embodiments, the cover 102 can include a flexible covering and a rigid frame disposed at least partially within the flexible covering. The terms “flexible” and “rigid”, when used in the context of “flexible covering” and “rigid frame”, are intended to be relative to each other, such that the flexible covering feels more flexible, as judged by an average adult user, than the rigid frame and the rigid frame is more rigid, as judged by the average adult user, than the flexible cover. Further details regarding such cases that can be modified to include first and second portions 108, 110 and a cord 106 can be found in U.S. patent application Ser. No. 16/853,544, which is incorporated herein by reference in its entirety.

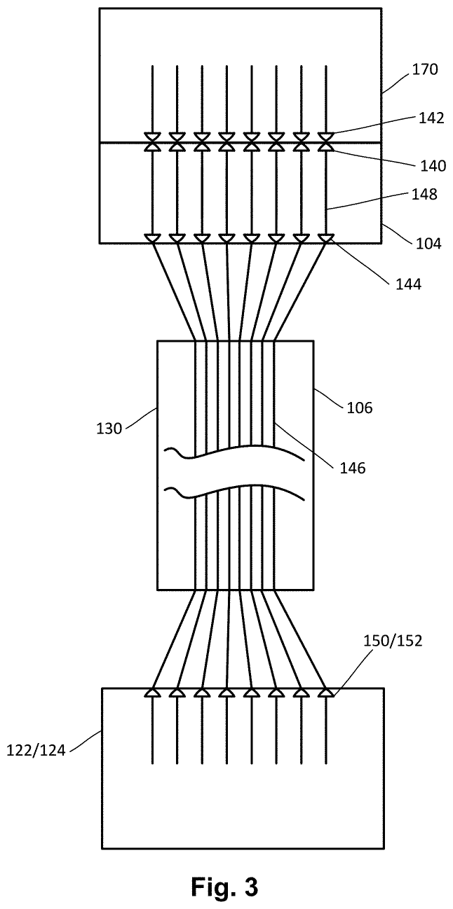

When the mobile device is received in the case 100, the cover 102 is arranged to cover at least a portion of all the side surfaces of the mobile device and to extend over at least a portion (or all) of the peripheral edges of the front and back surfaces of the mobile device to hold the mobile device in the case and to provide protection to the mobile device. The cover 102 can include one or more openings 119 to provide access to a speaker, a microphone, a camera, a light, a jack, buttons, switches, or the like on the mobile device. Optionally, the cover 102 can include one or more soft buttons (not shown) that are positioned in the flexible covering to coincide with positions (or possible positions) of buttons on the mobile device. The soft buttons are arranged so that depression of the soft buttons with sufficient force results in depression of the buttons of a mobile device received in the case 100. Optionally, the case 100 can include a stylus holder 118 extending from the cover 102 for holding a stylus 172 (FIG. 3B).

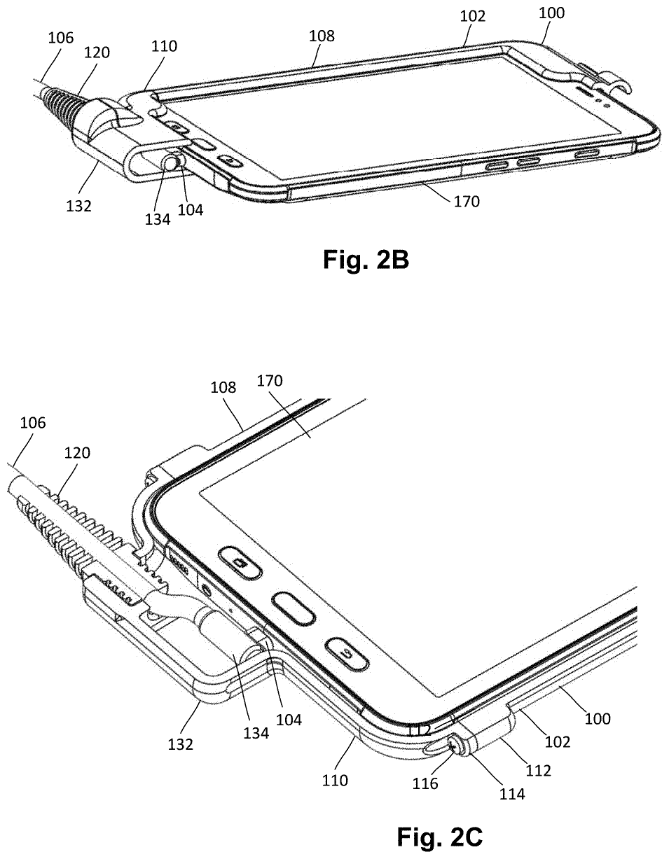

FIG. 2A illustrates the second portion 110 of the cover 102 with the male plug 104 disposed in the second portion and the cord 106 extending from the second portion. The fastener rings 114 and fasteners 116 are also illustrated. The male plug 104 includes first contacts 140 (FIG. 3) and is configured to be inserted into the female socket of the mobile device 170 so that the first contacts 140 of the male plug 104 are electrically coupled to the contacts 142 (FIG. 3) in the female socket of the mobile device. In at least some embodiments, the male plug 104 can be any suitable type of male connector, depending on the mobile device to be used, including, but not limited to, any type of USB connector (for example, any type of USB-A, USB-B, USB-C, Micro-USB, or Mini-USB connector) or a Lightning connector.

The cord 106 extends from the cover 102 and preferably includes a strain relief element 120 where the cord exits the cover. Any suitable strain relief element 120 can be used including, for example, the baffle-type strain relief in the illustrated embodiments.

The cord 106 includes a jacket 130 encasing wires 146 (FIG. 3). FIG. 3 is a schematic diagram illustrating the wires 146 electrically coupled to second contacts 144 on the male plug 104 which, in turn, are coupled to the first contacts 140 of the male plug through conductors 148, as illustrated in FIG. 3. The wires 146 extend along the cord 106.

In some embodiments, the cord 106 ends in a connector 122 such as, for example, any type of USB connector (for example, any type of USB-A, USB-B, USB-C, Micro-USB, or Mini-USB connector), Lightning connector, prong connector, audio- or video-type connector, connector for a vehicle cigarette lighter, or the like, where the wires 146 of the cord 106 are electrically coupleable to contacts 150 of the connector 122.

In some embodiments, the cord 106 is configured to be hardwired to a device 124, such as a power source, data source, or other device, which may be part of a vehicle, counter, cash register, or the like. When hardwired, the wires 146 of the cord 106 are electrically coupled to contacts 152 of the device 124. In at least some embodiments, the hardwiring of the cord 106 can hinder or prevent removal of the mobile device 170 and case 100 from the vehicle, store, or the like.

In at least some embodiments, the cord 106 can be clamped or otherwise fastened at one or more positions along the cord to a surface, device, vehicle, counter, or the like using a clamp 174 (FIG. 1A) or any other type of fastener.

FIGS. 2B and 2C are partial cross-sectional views of the case 100 to illustrate the arrangement of the cord 106 coupled to the male plug 104. Wires 146 (FIG. 3) within the cord 106 are electrically coupled to the second contacts 144 (FIG. 3) of the male plug 104. In at least some embodiments, the male plug 104 is arranged at or near a 90-degree angle relative to the cord 106. In at least some embodiments, the end of the male plug 104 near the cord 106 and the end of the cord may be potted in a material 134 such as epoxy or any other suitable material to stabilize the arrangement which, in at least some embodiments, is disposed in a housing 132 that is part of the second portion 110 of the cover 102. The housing 132 extends away from the cavity 103 and the remainder of the second portion. The strain relief element 120, which may be partially disposed in the housing 132, is provided on the cord 106 as it exits the housing 132 to resist breakage or damage to the cord.

In at least some embodiments, the mobile device 170 can be operated without a battery and, instead, power is provided to the mobile device through a power source, such as device 124 (or to a device coupled to the plug through connector 122), coupled to the cord 106 with power being directed from the power source, through the cord and the male plug 104 of the case 100, to the mobile device 170. This may be a further deterrent to removal of the mobile device 170 from the vehicle, store, or other site of use as the mobile device does not include a battery.

In at least some embodiments, the mobile device 170 may be designed to detect the presence of a battery in order to operate. In such embodiments, a dummy battery 176 may be placed in the mobile device 170. The dummy battery 176 may be capable of storing a relatively small amount of energy to pass a battery detection test of the mobile device. For example, the dummy battery 176 may contain a capacitor capable of storing sufficient energy to pass the battery detection test.

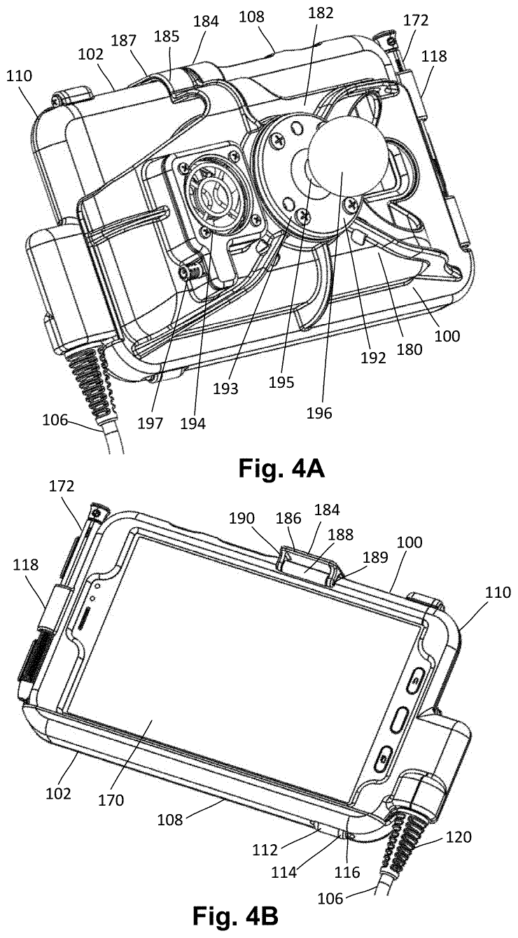

FIGS. 4A and 4B illustrate an optional accessory attachment 180 that is removably attached to the case 100 and mobile device 170. The accessory attachment 180 includes a base 182 and an attachment arm 184 extending from the base for attaching the accessory attachment to the case 100. The attachment arm 184 has a back cover engagement portion 185, a front cover engagement portion 186, and a cover width portion 187 extending between the back cover and front cover engagement portions. In at least some embodiments, the back cover and front cover engagement portions 185, 186 are arranged to fit snugly on the case 100 with the mobile device 170 disposed therein to retain the accessory attachment 180 on the case 100. In at least some embodiments, the front cover engagement portion 186 includes a roller 188 which can roll on an axle 189 held by two legs 190 to facilitate attachment of the accessory attachment 180 to the case 100.

The accessory attachment 180 can have attached or attachable one or more accessories, such as a mount 192 or a fan 194. The mount 192 can be any suitable mount that can be used to attach the case 100 and mobile device 170 to a mounting device. Non-limiting examples of mounts and mounting devices can be found at, for example, U.S. Pat. Nos. 5,845,885; 6,561,476; 7,320,50; 7,997,554; 8,454,178; 8,505,861; 9,831,904; RE42,060; RE42,581; and RE43,806, all of which are incorporated herein by reference in their entireties. In the illustrated embodiment, the mount 192 includes a mount base 193 that is coupled to the base 182 of the accessory attachment 180, a narrow neck 195 attached to the mount base, and a ball 196 attached to the narrow neck. One or more of the mount base 193, the narrow neck 195, of the ball 196 can be replaced by any other suitable mounting arrangement.

The fan 194 is coupled to the base 182 of the accessory attachment 180. In the illustrated embodiment, the fan 194 includes a jack 197 for coupling a cord that attaches to a power source for the fan. In at least some embodiments, the case 100 may include cord to couple to the jack 197 that can provide power or the case 100 may include a jack so that a cord can be attached between that jack and jack 197 to provide power to the fan.

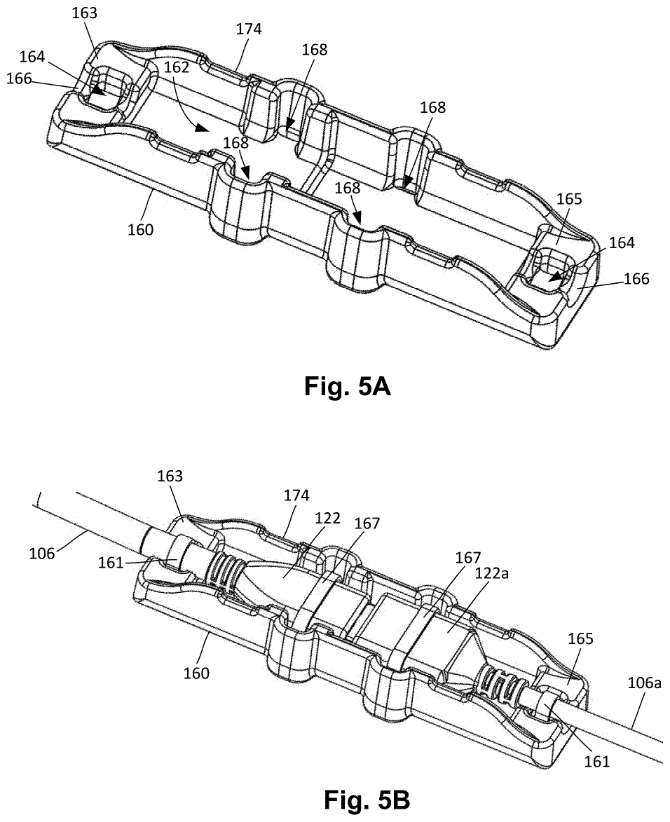

FIGS. 5A and 5B illustrate one embodiment of a clamp 174 that can receive the connector 122 attached to the cord 106 to clamp the cord to a surface, device, other article, or the like. The clamp 174 includes a body 160 that defines a channel 162 for receiving the connector 122 and a portion of the cord 106. In at least some embodiments, the channel 162 may also receive another connector 122a and portion of a cord 106a wherein the connector 122a is attached to the connector 122.

The body 160 of the clamp 174 includes two opposing cord tie openings 164 at the entry portion 163 and exit portion 165 of the clamp 174. In at least some embodiments, the entry portion 163 and exit portion 165 include rounded indents 166 into which the cords 106, 106a fit, as illustrated in FIG. 5B. Cable ties 161 or other fasteners can be placed around the cords 106, 106a, as illustrated in FIG. 5B, and pass through the cord tie openings 164 on both sides of the cords 106, 106a. The cable ties 161 can then be fastened around a portion of a surface, device, or other article to tie down the clamp 174 and cords 106, 106a to the surface, device, or other article.

The body 160 of the clamp 174 includes four connector tie openings 168 with two opposite each other at one position along the clamp and the other two opposite each other at a second position along the clamp. Cable ties 167 or other fasteners can be placed around the connectors 122, 122a and pass through two of the connector tie openings 168, as illustrated in FIG. 5B. The cable ties 167 can then be fastened around a portion of a surface, device, or other article to tie down the clamp 174 and connectors 122, 122a to the surface, device, or other article.

Alternatively, the cord 106 can be disposed along the length of the clamp 174 and two or more (or even all four) of the cable ties 161, 167 can be used to tie down the clamp and the cord to the surface, device, or other article.

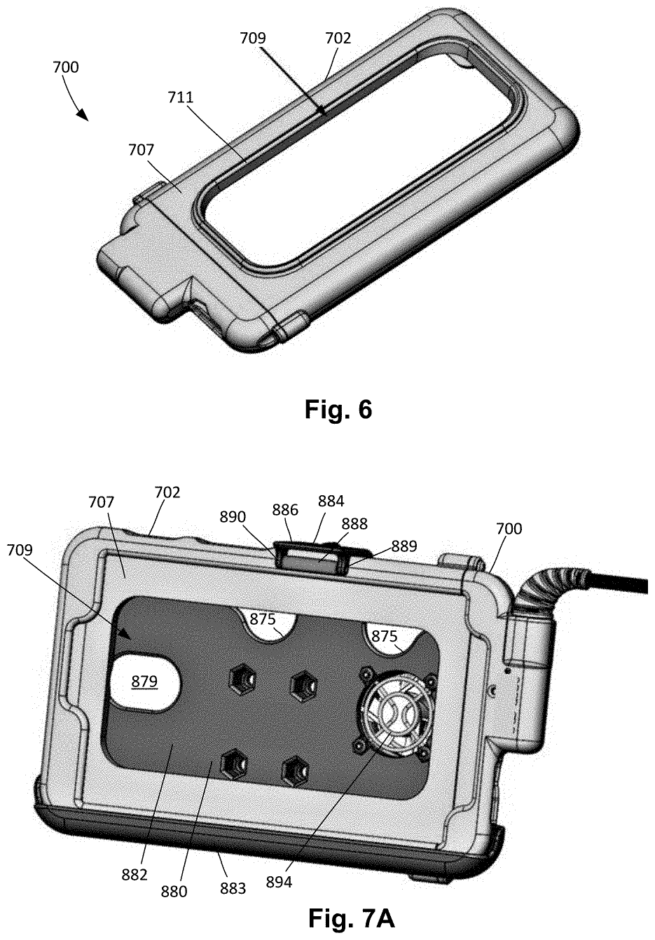

FIG. 6 illustrates one embodiment of a case 700, which can include all of the aspects and options described above for case 100, that includes a cover 702 with a back panel 707 having a relatively large window 709 and an optional raised rim 711 disposed around the window and extending away from a portion of the cover adjacent the raised rim. In at least some embodiments, the raised rim 711 extends around only a portion of the window 709, such as along one, two, or three sides or portions of sides of the window. In at least some embodiments, the raised rim 711 extends around the entire perimeter of the window as illustrated in FIG. 6.

In at least some embodiments, the window 709 has an area that is configured to expose at least 25, 30, 40, 50, 60, 65, 70, or 75 percent of the area of the back surface of the mobile device 170 that the cover is sized to receive. In at least some embodiments, the window 709 has an area that is at least 25, 30, 40, 50, 60, 65, 70, or 75 percent of the area of the back panel 707 or the back surface of the case 700.

At least some mobile devices generate substantial heat during operation and a case can retain some of that heat. In at least some embodiments, the window 709 can facilitate cooling of the mobile device as much of the back of the mobile device is not covered by the case 700. Providing a window 709 can facilitate dissipation of the heat generated by the mobile device.

In at least some embodiments, the window 709 or the raised rim 711 (or both) can facilitate a user grasping the mobile device. This may be an even more useful advantage for tablets or larger mobile phones which may be more difficult to hold with one hand. The window 709 or raised rim 711 (or both) can facilitate placement of the user's fingers along the raised rim 711 or the rim of the window 709 for more securely grasping the mobile device.

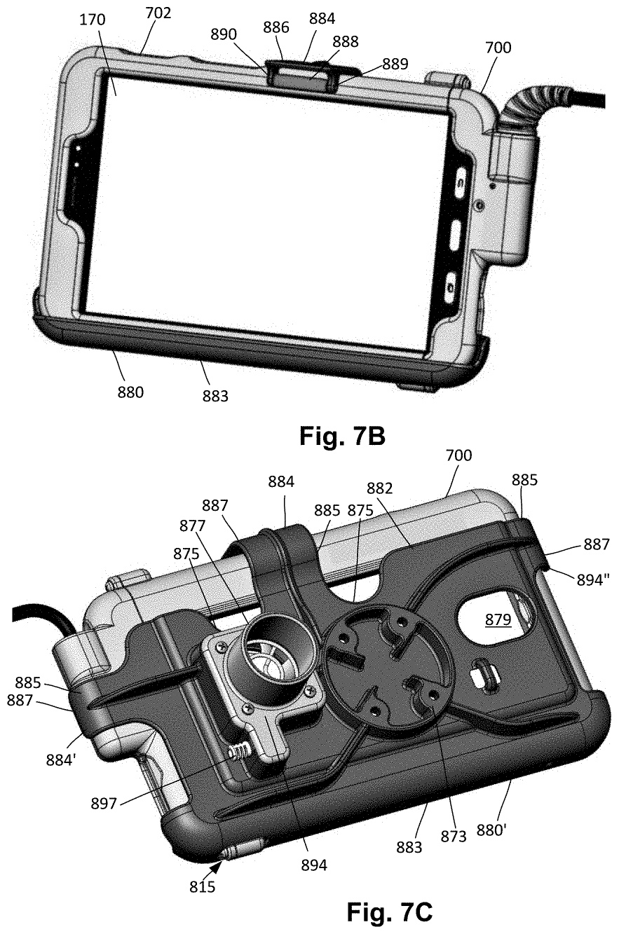

FIGS. 7A to 7C illustrate the case 700 (which has the window 709) with an optional accessory attachment 880, 880′ that is removably attached to the case 700 and mobile device 170. The accessory attachment 880 of FIGS. 7A and 7B includes a base 882, an attachment arm 884, extending from the base for attaching the accessory attachment to the case 700, and an attachment tray 883 extending from the base and arranged to receive and retain a portion of the case 700 and mobile device 170. The accessory attachment 880′ of FIG. 7C also includes the base 882 and the attachment tray 883, but includes three attachment arms 884, 884′, and 884″. It will be understood that the accessory attachment 180 of FIGS. 4A and 4B could also be attached to the case 700 or that the accessory attachments 880, 880′ could be attached to the case 100 described above.

The attachment arm 884 has a back cover engagement portion 885 (FIG. 7C), a front cover engagement portion 886, and a cover width portion 887 (FIG. 7C) extending between the back cover and front cover engagement portions. In at least some embodiments, the back cover and front cover engagement portions 885, 886 are arranged to fit snugly on the case 700 with the mobile device 170 disposed therein to retain the accessory attachment 880 on the case 700. In at least some embodiments, the front cover engagement portion 886 includes a roller 888 which can roll on an axle 889 held by two legs 890 to facilitate attachment of the accessory attachment 880, 880′ to the case 100. The attachment arms 884′, 884″ may be the same as attachment arm 884 or may be different, such as not including a roller 888, axle 889, and legs 890.

In at least some embodiments, the attachment tray 883 is formed to receive a portion of the case 700 and mobile device 170 including portions of the back, front, and one or more sides of the case and mobile device. In the illustrated embodiments, the attachment tray 883 has a shape of an elongated bowl or of a channel with or without one or more closed ends. In at least some embodiments, the attachment tray 883 is configured to receive the portions of the back, front, and one or more sides of the case and mobile device. In at least some embodiments, the attachment tray 883 includes an opening 815 to so that the fastener receiver 112, fastener ring 114, and fastener 116 (FIG. 1A) can extend out of the attachment tray 883, as illustrated in FIG. 7C.

In at least some embodiments, the base 882 includes one or more openings 879 that at least partially overlap with the window 709 of the case 700. These opening(s) 879, in conjunction with the window 709, may facilitate cooling or heat dissipation of the mobile device. In at least some embodiments, the base 882 has contours 875 to reduce overlap of the base with the window 709 of the case.

The accessory attachment 880, 880′ can have attached or attachable one or more accessories, such as a mount 192 (FIG. 4A) or a fan 894. The mount 192 is described above with respect to accessory attachment 180. FIG. 7C illustrates a mounting site 873 for attachment of a mount 192.

The fan 894 is coupled to the base 882 of the accessory attachment 880, 880′ and can facilitate cooling of the mobile device 170 through the flow of air over the case 700 or mobile device. In at least some embodiments, the fan 894 draws in air from the environment which may be cooler than air near the mobile device 170. The fan 894 (or fan 194) can optionally include a fitting 877 that can be attached to a source of cooling air (for example, through a tube or hose or the like) to further facilitate cooling of the mobile device or heat dissipation.

In the illustrated embodiment, the fan 894 includes a jack 897 for coupling a cord that attaches to a power source for the fan. In at least some embodiments, the case 700 may include cord to couple to the jack 897 that can provide power or the case 700 may include a jack so that a cord can be attached between that jack and jack 897 to provide power to the fan.

Cases that can be modified to include a window 709 or raised rim 711 can be found at, for example, U.S. Pat. Nos. 9,195,279; 9,331,444; 9,529,387; 9,602,639; 9,632,535; 9,706,026; 10,050,658; 10,054,984; 10,389,399; 10,454,515; and 10,630,334 and U.S. patent application Ser. Nos. 16/835,544; 16/853,565; and Ser. No. 16/866,156, all of which are incorporated herein by reference in their entireties. For example, the window 709 or raised rim 711 can be used with the two piece cover 102 described above or for the single unitary piece covers described in these cited references (for example, the cases in FIGS. 6-15, 42-45, and 55B-56B of U.S. Pat. No. 10,389,399). As another example, the window 709 or raised rim 711 can be used with a case 100 having a cord 106 as described above or with cases that, instead of a cord, have a contactor disposed in the cover and having contacts electrically coupled to the contacts of the male plug and exposed for coupling to an external device such as a docking cradle, adapter, or the like as described in these cited references (for example, the cases in FIGS. 6-15, 42-45, and 55B-56B of U.S. Pat. No. 10,389,399). In addition, the accessory attachment 180, 880, 880′ can be modified for use with the cases in these cited references (for example, the cases in FIGS. 6-15, 42-45, and 55B-56B of U.S. Pat. No. 10,389,399).

The above specification provides a description of the manufacture and use of the invention. Since many embodiments of the invention can be made without departing from the spirit and scope of the invention, the invention also resides in the claims hereinafter appended.

What is claimed as new and desired to be protected by Letters Patent of the United States is:

1. A case for a mobile device, the case comprising:
a cover defining a cavity configured for receiving and holding the mobile device, the cover comprising a back panel and a window formed in the back panel, wherein the window comprises at least 30% of the area of the back panel;
a male plug disposed in the second portion of the cover, extending into the cavity defined by the cover, and configured for insertion into a female socket of the mobile device, the male plug comprising a plurality of first contacts configured for mating with contacts of the mobile device; and
an accessory attachment coupleable to the cover and comprising a fan configured to be positioned over the window formed in the back panel of the cover to facilitate heat dissipation from the mobile device.

2. The case of claim 1, wherein the accessory attachment further comprises a fitting on the fan for attachment to a source of cooling air.

3. The case of claim 1, wherein the cover further comprises a raised rim around at least a portion of the window and extending away from an adjacent portion of the cover.

4. The case of claim 3, wherein the raised rim extends around an entire perimeter of the window.

5. The case of claim 1, wherein the accessory attachment comprises a base and at least one attachment arm extending from the base and configured to engage a front surface and a back surface of the cover to attach the accessory attachment to the cover.

6. The case of claim 5, wherein at least one of the at least one attachment arm comprises a roller configured to engage the cover and to roll as the roller is passed over the cover.

7. The case of claim 1, wherein the accessory attachment further comprises a mounting site configured for attachment of a mount.

8. The case of claim 1, wherein the accessory attachment further comprises a mount.

9. The case of claim 1, wherein the accessory attachment comprises a base with the fan attached to the base and the base defining at least one opening that, when the accessory attachment is coupled to the cover, overlaps with the window of the cover.

10. The case of claim 1, wherein the accessory attachment comprises a base and an attachment tray extending from the base and configured to receive a portion of the cover.

11. The case of claim 1, further comprising a cord extending out of the cover and comprising a jacket and a plurality of wires disposed in the jacket and electrically coupled to the first contacts of the male plug.

12. The case of claim 1, further comprising a contactor disposed in the cover and comprising a plurality of second contacts electrically coupled to the first contacts of the male plug and exposed for coupling to an external device.

13. The case of claim 1, wherein the cover comprises a first portion and a second portion removably attachable to the first portion.

14. The case of claim 1, wherein the cover is a single unitary piece.

15. An arrangement, comprising:
the case of claim 1; and
the mobile device receivable within the case and comprising the female socket configured to receive the male plug of the adapter of the case.

16. A case for a mobile device, the case comprising:
a cover defining a cavity sized for receiving and holding the mobile device, the cover comprising a back panel and a window formed in the back panel, wherein the window comprises at least 30% of the area of a back surface of the mobile device;
a male plug disposed in the second portion of the cover, extending into the cavity defined by the cover, and configured for insertion into a female socket of the mobile device, the male plug comprising a plurality of first contacts configured for mating with contacts of the mobile device; and
an accessory attachment coupleable to the cover and comprising a fan configured to be positioned over the window formed in the back panel of the cover to facilitate heat dissipation from the mobile device.

17. The case of claim 16, wherein the accessory attachment further comprises a fitting on the fan for attachment to a source of cooling air.

18. The case of claim 16, wherein the cover further comprises a raised rim around at least a portion of the window and extending away from an adjacent portion of the cover.

19. The case of claim 18, wherein the raised rim extends around an entire perimeter of the window.

20. An arrangement, comprising:
the case of claim 16; and
the mobile device receivable within the case and comprising the female socket configured to receive the male plug of the adapter of the case.
